(19) United States
(12) Patent Application Publication
(10) Pub. No.: US 2025/0081558 A1
(43) Pub. Date: Mar. 6, 2025

(54) SEMICONDUCTOR DEVICE HAVING A REDUCED HEIGHT GATE ELECTRODE LAYER

(71) Applicant: TEXAS INSTRUMENTS INCORPORATED, Dallas, TX (US)

(72) Inventor: Manoj Mehrotra, Plano, TX (US)

(21) Appl. No.: 18/458,280

(22) Filed: Aug. 30, 2023

(51) Int. Cl. H01L 29/08; H01L 21/8234; H01L 27/088; H01L 29/66

(52) U.S. Cl. CPC H10D 62/151; H10D 64/021; H10D 84/0147; H10D 84/038; H10D 84/83

(57) ABSTRACT

The present disclosure generally relates to a semiconductor device having a reduced height gate electrode layer. In an example, a semiconductor device includes a substrate, a gate dielectric layer, a gate electrode layer, a doped source/drain region, and a dielectric layer. The gate dielectric layer is on a surface of the substrate. The gate electrode layer is on the gate dielectric layer. The doped source/drain region is in the substrate and has a metallurgical junction parallel to a plane coplanar with the surface of the substrate. The metallurgical junction extends to a first vertical distance from the surface of the substrate. The gate electrode layer has a top surface that is a second vertical distance away from the surface of the substrate. The second vertical distance is equal to or less than half of the first vertical distance. The dielectric layer is over the substrate and the gate electrode layer.

### BACKGROUND

Transistors, such as field effect transistors (FETs), are ubiquitous in today's world. Various electronic devices rely on transistors for proper functionality. Transistors, in some forms, are continuously being developed and improved. As the advances in the design of integrated circuits and semiconductor fabrication continue to take place, improvements in semiconductor devices, including power FETs, are also being concomitantly pursued.

### SUMMARY

An example described herein is a semiconductor device. The semiconductor device includes a substrate, a gate dielectric layer, a gate electrode layer, a doped source/drain region, and a dielectric layer. The substrate includes a semiconductor material. The gate dielectric layer is on a surface of the substrate. The gate electrode layer is on the gate dielectric layer. The doped source/drain region is in the substrate. The doped source/drain region has a metallurgical junction in the substrate, and the metallurgical junction is parallel to a plane coplanar with the surface of the substrate. The metallurgical junction extends to a first vertical distance from the surface of the substrate. The gate electrode layer has a top surface distal from the substrate. The top surface of the gate electrode layer is a second vertical distance away from the surface of the substrate. The second vertical distance is equal to or less than half of the first vertical distance. The dielectric layer is over the substrate and the gate electrode layer.

Another example is a method. A gate stack is formed on a gate dielectric layer disposed on a surface of a semiconductor substrate. The gate stack includes a gate electrode layer and a hardmask layer over the gate electrode layer. While the hardmask layer is over the gate electrode layer, a source/drain region is formed in the semiconductor substrate. Forming the source/drain region includes implanting a dopant into the semiconductor substrate. After implanting the dopant, a dielectric layer is formed over the gate electrode layer.

A further example is a semiconductor device. The semiconductor device includes a transistor and a dielectric layer over the transistor. The transistor includes a first source/drain region, a second source/drain region, and a gate electrode layer. The first source/drain region is in a semiconductor substrate, and the second source/drain region is in the semiconductor substrate. The gate electrode layer is over the semiconductor substrate and is laterally between the first source/drain region and the second source/drain region. The top surface of a semiconductor material of the semiconductor substrate underlies the gate electrode layer. The first source/drain region has a metallurgical junction in the semiconductor substrate, and the metallurgical junction is parallel to a plane coplanar with the top surface. The metallurgical junction extends to a first vertical distance from the top surface. The gate electrode layer has a top surface distal from the semiconductor substrate. The top surface of the gate electrode layer is a second vertical distance away from the top surface. The second vertical distance is equal to or less than half of the first vertical distance.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross section view of an integrated circuit (IC) structure according to some examples.

FIGS. 2, 3, 4, 5, 6, 7, 8, 9, 10, 11, and 12 are cross-sectional views of the IC structure of FIG. 1 at various stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to a semiconductor device having a reduced height gate electrode layer. In some examples, a semiconductor device includes a substrate, a gate dielectric layer, a gate electrode layer, and a doped source/drain region. The gate dielectric layer is on a surface of the substrate, and the gate electrode layer is on the gate dielectric layer. The doped source/drain region is in the substrate. The doped source/drain region has a metallurgical junction in the substrate that is parallel to a plane coplanar with the surface of the substrate. The metallurgical junction is at a depth from the surface of the substrate. The gate electrode layer has a top surface distal from the substrate that is a height away from the surface of the substrate. A dielectric layer is over the substrate and the gate electrode layer. In such examples, a height of the gate electrode layer may be reduced, which may reduce a sidewall surface area of the gate electrode layer. For example, the height may be equal to or less than half of the depth of the metallurgical junction. The reduced sidewall surface area may reduce parasitic capacitances, such as a parasitic capacitance between the gate electrode layer and a contact electrically connected to the doped source/drain region, a parasitic capacitance between the gate electrode layer and the doped source/drain region, and/or a parasitic capacitance between the gate electrode layer and another gate electrode layer. With reduced parasitic capacitance, operational speed of the semiconductor device may be increased due to a reduced resistance-capacitance (RC) time constant. Other benefits and advantages may also be achieved.

Various examples are described subsequently. Although the specific examples may illustrate various aspects of the above generally described features, examples may incorporate any combination of the above generally described features (which are described in more detail in examples below).

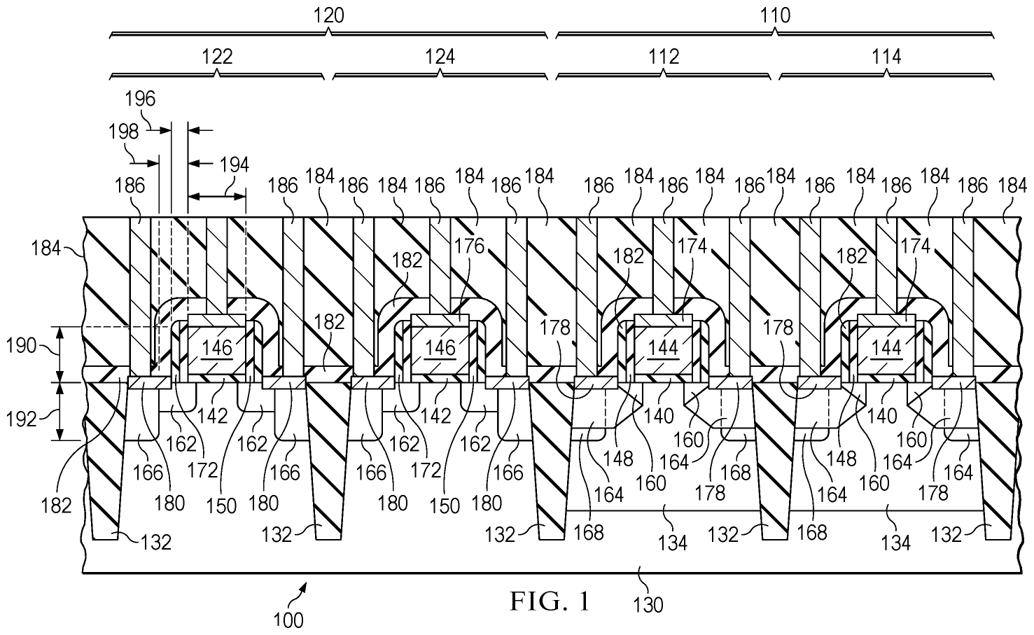

FIG. 1 illustrates a cross section view of an integrated circuit (IC) structure 100 according to some examples. An IC includes the IC structure 100. The IC structure 100 includes a p-type field effect transistor (pFET) region 110 where one or more kinds of pFETs may be formed. For example, the pFET region 110 may include a logic pFET 112 and a static random access memory (SRAM) pFET 114 as shown in FIG. 1. The IC structure 100 also includes an n-type field effect transistor (nFET) region 120 where one or more kinds of nFETs may be formed. For example, the nFET region 120 may include a logic nFET 122 and a SRAM nFET 124 as shown in FIG. 1. The pFETs 112, 114 and nFETs 122, 124 are each an example semiconductor device according to various examples.

The IC structure 100 includes a semiconductor substrate 130. The semiconductor substrate 130 may be or include a bulk semiconductor substrate, a semiconductor-on-insulator (SOI) substrate, or any other appropriate substrate. The semiconductor substrate 130 may also include a support (or handle) substrate and an epitaxial layer epitaxially grown on the support substrate. In some examples, the semiconductor substrate 130 is or includes a silicon substrate (which may be singulated from a bulk silicon wafer at the conclusion of semiconductor processing). In further examples, the semiconductor substrate 130 includes a silicon substrate with an epitaxial silicon layer grown thereon. The semiconductor substrate 130 is or includes a semiconductor material in and/or on which devices, such as the pFETs 112, 114 and nFETs 122, 124, are formed. In some examples, the semiconductor material is or includes silicon (Si), and in other examples, the semiconductor material may be or include silicon germanium (SiGe), gallium arsenide (GaAs), gallium nitride (GaN), the like, or a combination thereof. The semiconductor substrate 130 has a top major surface in and/or on which devices (e.g., the pFETs 112, 114 and nFETs 122, 124) are formed.

Isolation structures 132 are on the semiconductor substrate 130. In the illustrated example, the isolation structures 132 are shallow trench isolation structures (STIs) extending from the top major surface of the semiconductor substrate 130 into the semiconductor substrate 130. The isolation structures 132 may include, for example, a layer of silicon nitride conformal along surfaces of a respective trench in the semiconductor substrate 130 and silicon oxide over and on the layer of silicon nitride. In other examples, the isolation structures 132 may be field oxide structures, such as local oxidation of silicon (LOCOS) structures, at the top major surface of the semiconductor substrate 130. The isolation structures 132 laterally define active areas in the semiconductor substrate 130 in which respective pFETs 112, 114 and nFETs 122, 124 are formed.

In the illustrated example, the semiconductor material of the semiconductor substrate 130 is p-doped. Hence, an n-type doped well 134 is in the semiconductor substrate 130 in the pFET region 110. A concentration of the n-type dopant of the n-type doped well 134 is greater than a concentration of the p-type dopant of the p-type doped semiconductor substrate 130. In some examples, the semiconductor substrate 130 is p-doped with a p-type dopant (e.g., boron (B)) with a concentration in a range from 1×10¹⁴ cm⁻³ to 1×10¹⁵ cm⁻³, and the n-type doped well 134 is doped with an n-type dopant (e.g., phosphorus (P) or arsenic (As)) with a concentration in a range from 1×10¹⁵ cm⁻³ to 1×10¹⁶ cm⁻³. Other doping concentrations may be implemented. In other examples, the semiconductor material of the semiconductor substrate 130 may be n-doped, and a p-type doped well may be in the semiconductor substrate 130 in the nFET region 120.

Respective gate dielectric layers 140 are over and on the top major surface of the semiconductor substrate 130 in the active areas in the pFET region 110, and respective gate dielectric layers 142 are over and on the top major surface of the semiconductor substrate 130 in the active areas in the nFET region 120. The gate dielectric layers 140, 142 may be or include silicon oxide, silicon nitride, hafnium oxide, the like, or a combination thereof. In some examples, the gate dielectric layers 140 may be or include a material that is a high-k dielectric material, e.g., having a dielectric constant (k) that is greater than the dielectric constant of silicon dioxide (SiO₂). In some examples, respective thicknesses of the gate dielectric layers 140, 142 may be in a range from 10 Angstroms (Å) to 30 Å.

Respective gate electrode layers 144 are over and on the gate dielectric layers 140, and respective gate electrode layers 146 are over and on the gate dielectric layers 142. The gate electrode layers 144, 146, in some examples, are or include silicon, such as doped polysilicon. In examples in which the gate electrode layers 144, 146 are doped polysilicon, the gate electrode layers 144 may be p-doped with a p-type dopant at a concentration in a range from 1×10²⁰ cm⁻³ to 5×10²¹ cm⁻³, and the gate electrode layers 146 may be n-doped with an n-type dopant at a concentration in a range from 1×10²⁰ cm⁻³ to 5×10²¹ cm⁻³.

First gate spacers 148 are on sidewall surfaces of the gate electrode layers 144, and first gate spacers 150 are on sidewall surfaces of the gate electrode layers 146. The first gate spacers 148, 150 may be or include silicon oxide, silicon nitride, silicon oxynitride, silicon oxycarbide, silicon oxycarbon nitride, the like, or a combination thereof.

P-type lightly doped drain regions (LDDs) 160 are in the semiconductor substrate 130 in the active areas in the pFET region 110, and n-type LDDs 162 are in the semiconductor substrate 130 in the active areas in the nFET region 120. For each of the pFETs 112, 114, first and second p-type LDDs 160 are on opposing lateral sides of the respective gate dielectric layer 140 and gate electrode layer 144. The p-type LDDs 160 may in part underlie the gate dielectric layer 140 and gate electrode layer 144 and extend in the semiconductor substrate 130 laterally away from the gate dielectric layer 140 and gate electrode layer 144. For each of the nFETs 122, 124, first and second n-type LDDs 162 are on opposing lateral sides of the respective gate dielectric layer 142 and gate electrode layer 146. The n-type LDDs 162 may in part underlie the gate dielectric layer 142 and gate electrode layer 146 and extend in the semiconductor substrate 130 laterally away from the gate dielectric layer 142 and gate electrode layer 146. A concentration of the p-type dopant of the p-type LDDs 160 is greater than the concentration of the n-type dopant of the n-type doped well 134, and a concentration of the n-type dopant of the n-type LDDs 162 is greater than the concentration of the p-type dopant of the p-type doped semiconductor substrate 130. In some examples, the p-type LDDs 160 are p-doped with a p-type dopant with a concentration in a range from 1×10¹⁹ cm⁻³ to 1×10²¹ cm⁻³, and the n-type LDDs 162 are doped with an n-type dopant with a concentration in a range from 1×10¹⁹ cm⁻³ to 1×10²¹ cm⁻³. Other doping concentrations may be implemented.

Embedded stressors 164 are in the semiconductor substrate 130 in the active areas in the pFET region 110. For each of the pFETs 112, 114, a pair of embedded stressors 164 is on opposing lateral sides of the respective gate dielectric layer 140 and gate electrode layer 144. The embedded stressors 164 extend in the semiconductor substrate 130 laterally away from the gate dielectric layer 140 and gate electrode layer 144. In some examples, such as when the semiconductor substrate 130 is silicon, the embedded stressors 164 may be silicon germanium (SiGe) or another stressor material epitaxially grown in recesses in the semiconductor substrate 130. The embedded stressors 164 are at least partially doped with a p-type dopant, which may form p-type source/drain regions 168 of the pFETs 112, 114. In some examples, the p-type source/drain regions 168 are in the embedded stressors 164. In some examples, the p-type source/drain regions 168 are partially in the embedded stressors 164 and extend into the semiconductor material of the semiconductor substrate 130 below the embedded stressors 164 as shown in FIG. 1. A concentration of the p-type dopant of the p-type source/drain regions 168 is greater than the concentration of the p-type dopant of the p-type LDDs 160 and is greater than the concentration of the n-type dopant of the n-type doped well 134. In some examples, the p-type source/drain regions 168 are p-doped with a p-type dopant with a concentration in a range from 1×10²⁰ cm⁻³ to 1×10²² cm⁻³. Other doping concentrations may be implemented.

N-type source/drain regions 166 are in the semiconductor substrate 130 in the active areas in the nFET region 120. For each of the nFETs 122, 124, first and second n-type source/drain regions 166 are on opposing lateral sides of the respective gate dielectric layer 142 and gate electrode layer 146. The n-type source/drain regions 166 extend in the semiconductor substrate 130 laterally away from the gate dielectric layer 142 and gate electrode layer 146. A concentration of the n-type dopant of the n-type source/drain regions 166 is greater than the concentration of the n-type dopant of the n-type LDDs 162 and is greater than the concentration of the p-type dopant of the p-type doped semiconductor substrate 130. In some examples, the n-type source/drain regions 166 are doped with an n-type dopant with a concentration in a range from 1×10¹⁹ cm⁻³ to 1×10²² cm⁻³. Other doping concentrations may be implemented.

Second gate spacers 170 are along sidewall surfaces of respective first gate spacers 148, and second gate spacers 172 are along sidewall surfaces of respective first gate spacers 150. A first gate spacer 148 is disposed between a respective second gate spacer 170 and a gate electrode layer 144, and a first gate spacer 150 is disposed between a respective second gate spacer 172 and a gate electrode layer 146. The second gate spacers 170, 172 may be or include silicon nitride, silicon oxynitride, silicon oxycarbide, silicon oxycarbon nitride, the like, or a combination thereof.

As illustrated, metal-semiconductor compound 174 is on respective top surfaces of the gate electrode layers 144, and metal-semiconductor compound 176 is on respective top surfaces of the gate electrode layers 146. When the gate electrode layers 144, 146 are or include a semiconductor material, such as silicon (e.g., polysilicon), metal-semiconductor compound 174, 176 may be formed on the top surface of the gate electrode layer 144, 146. The metal-semiconductor compounds 174, 176 may be a silicide (e.g., TiSix, CoSix, NiSix, PtSix), a germanicide, or the like. In some examples, the metal-semiconductor compound 174, 176 may be omitted. Metal-semiconductor compound 178 is on respective top surface of the embedded stressors 164, and metal-semiconductor compound 180 is on the top major surface of the semiconductor substrate 130 at the n-type source/drain regions 166. The metal-semiconductor compounds 178, 180 may be a silicide (e.g., TiSix, CoSix, NiSix, PtSix), a germanicide, or the like. In some examples, the metal-semiconductor compound 178, 180 may be omitted.

A conformal dielectric layer 182 is over the semiconductor substrate 130. The conformal dielectric layer 182 is conformally over and on the isolation structures 132, the metal-semiconductor compound 174, 176, 178, 180, the first gate spacers 148, 150, and the second gate spacers 170, 172. The conformal dielectric layer 182 may be or include silicon nitride, silicon oxynitride, or another dielectric layer. The conformal dielectric layer 182 may be a stressor layer, an etch stop layer, or the like. A dielectric layer 184 is over and on the conformal dielectric layer 182. The dielectric layer 184 may be or include silicon oxide, silicon nitride, or the like. The dielectric layer 184 may be a pre-metal dielectric (PMD), an inter-layer dielectric (ILD), or the like.

Contacts 186 extend through the dielectric layer 184 and conformal dielectric layer 182 and contact respective metal-semiconductor compound 174, 176, 178, 180. The contacts 186 may each include one or more barrier and/or adhesion layers (e.g., titanium nitride (TiN), tantalum nitride (TaN), the like, or a combination thereof) conformally in a respective opening through the dielectric layer 184 and conformal dielectric layer 182, and a fill metal (e.g., tungsten (W), copper (Cu), aluminum (Al), the like, or a combination thereof) over and/or on the barrier and/or adhesion layer(s).

Generally, as illustrated, each pFET 112, 114 includes a gate structure, where the gate structure includes a gate dielectric layer 140, a gate electrode layer 144 on the gate dielectric layer 140, and a metal-semiconductor compound 174 on the gate electrode layer 144. Each pFET 112, 114 includes gate spacer structures on opposing sides of the gate structure, where a gate spacer structure includes a first gate spacer 148 on a sidewall surface of the gate structure and a second gate spacer 170 on the first gate spacer 148. Each pFET 112, 114 includes a first p-type LDD 160 and a second p-type LDD 160 in the semiconductor substrate 130. The first and second p-type LDDs 160 are on opposing lateral sides of the gate structure, and a channel region in the semiconductor substrate 130 underlying the gate structure (e.g., underlying the gate dielectric layer 140) is between the first p-type LDD 160 and the second p-type LDD 160. Further, each pFET 112, 114 includes a first p-type source/drain region 168 and a second p-type source/drain region 168. Each p-type source/drain region 168 is, at least partially, in a respective embedded stressor 164 and may extend below the embedded stressor 164 into the semiconductor substrate 130. Each p-type source/drain region 168 extends laterally from a respective p-type LDD 160 away from the gate structure. Hence, the p-type LDDs 160 and channel region are disposed between the p-type source/drain regions 168.

Generally, as illustrated, each nFET 122, 124 includes a gate structure, where the gate structure includes a gate dielectric layer 142, a gate electrode layer 146 on the gate dielectric layer 142, and a metal-semiconductor compound 176 on the gate electrode layer 146. Each nFET 122, 124 includes gate spacer structures on opposing sides of the gate structure, where a gate spacer structure includes a first gate spacer 150 on a sidewall surface of the gate structure and a second gate spacer 172 on the first gate spacer 150. Each nFET 122, 124 includes a first n-type LDD 162 and a second n-type LDD 162 in the semiconductor substrate 130. The first and second n-type LDDs 162 are on opposing lateral sides of the gate structure, and a channel region in the semiconductor substrate 130 underlying the gate structure (e.g., underlying the gate dielectric layer 142) is between the first n-type LDD 162 and the second n-type LDD 162. Further, each nFET 122, 124 includes a first n-type source/drain region 166 and a second n-type source/drain region 166. Each n-type source/drain region 166 extends laterally from a respective n-type LDD 162 away from the gate structure. Hence, the n-type LDDs 162 and channel region are disposed between the n-type source/drain regions 166.

For any of the pFETs 112, 114 and nFET 122, 124, the gate electrode layer 144, 146 has a top surface at a first dimension 190 (e.g., a vertical distance or height) distal from the top major surface of the semiconductor substrate 130 (e.g., underlying and/or interfacing with the gate dielectric layer 140, 142). The p-type source/drain regions 168 or n-type source/drain regions 166 each form, in part, a metallurgical (e.g., p-n) junction parallel to a plane coplanar with the top major surface of the semiconductor substrate 130 at a second dimension 192 (e.g., a vertical distance or depth) from the top major surface of the semiconductor substrate 130. For the pFETs 112, 114, a p-type source/drain region 168 is the p-type region of the metallurgical junction, and the n-type doped well 134 is the n-type region of the metallurgical junction. The metallurgical junction forms where the p-type dopant concentration of the p-type source/drain region 168 becomes equal to the n-type dopant concentration in the n-type doped well 134. For the nFETs 122, 124, an n-type source/drain region 166 is the n-type region of the metallurgical junction, and the p-type doped semiconductor material of the semiconductor substrate 130 is the p-type region of the metallurgical junction. The metallurgical junction forms where the n-type dopant concentration of the n-type source/drain region 166 becomes equal to the p-type dopant concentration in the p-type doped semiconductor material of the semiconductor substrate 130.

In some examples, the first dimension 190 is less than the second dimension 192. More particularly, in some examples, the first dimension 190 is equal to or less than half of the second dimension 192. In some examples, the first dimension 190 is equal to or less than 600 Å, and more particularly, equal to or less than 400 Å. In some examples, the second dimension 192 is equal to or greater than 700 Å, and more particularly, equal to or greater than 1,000 Å.

According to some examples, the gate electrode layer 144, 146 may be implanted with a dopant (e.g., a p-type or n-type dopant) that is implanted to form the corresponding source/drain regions of the pFET 112, 114 or nFET 122, 124. During the implantation, a hardmask layer is over and on the gate electrode layer 144, 146, which may be sufficiently thick to prevent a substantial amount of the dopants from being implanted into the channel region in the semiconductor substrate 130 underlying the gate electrode layer 144, 146 despite, e.g., the first dimension 190 being less than a depth to which the source/drain regions are formed (e.g., to second dimension 192). Hence, according to some examples, the channel region underlying a gate structure is substantially free of dopants (e.g., excluding possible diffusion of dopants) that were implanted into the gate electrode layer 144, 146 of the gate structure and into the semiconductor substrate 130 to form the corresponding source/drain regions.

Some examples may achieve a reduced first dimension 190 for a given technology node while other dimensions (e.g., metallurgical junction depths of the source/drain regions, distances between LDD regions under the gate structure which may be referred to as channel lengths, lateral width dimension of the gate structure) are maintained for the given technology node, which may result in a reduced parasitic capacitance. A parasitic capacitance may be formed between a sidewall surface of a gate electrode layer 144, 146 and a contact 186, between the sidewall surface of a gate electrode layer 144, 146 and a source/drain region, and between sidewall surface of a gate electrode layer 144, 146 and a sidewall surface of another gate electrode layer 144, 146. Reducing a dimension (e.g., height) of the gate electrode layer 144, 146 reduces the area of the sidewall surface of the gate electrode layer 144, 146 for forming the parasitic capacitance. Since the parasitic capacitance is generally a function of the area of the sidewall surface of the gate electrode layer 144, 146, the parasitic capacitance may be reduced by the reduction in the area of the sidewall surface of the gate electrode layer 144, 146. Reducing the parasitic capacitance reduces a resistance-capacitance (RC) time constant, which may permit increased speed of the FETs.

In some examples, the gate electrode layer 144, 146 has a third dimension 194 (e.g., a lateral dimension or width) between opposing sidewall surfaces of the gate electrode layer 144, 146. The third dimension 194 is a width of the gate electrode layer 144, 146 parallel to a channel length direction of the channel region underlying the gate electrode layer 144, 146. In some examples, the third dimension 194 may be in a range from 25 nm to 1 μm. According to some examples, the first dimension 190 is less than or equal to twice the third dimension 194, and more particularly, is in a range from one to two times the third dimension 194. As illustrated subsequently, the first dimension 190 may be reduced for a given technology node while a third dimension 194 for the given technology node is maintained, which may be determined by the channel length requirements for the given technology node—e.g., a target channel length.

In some examples, a gate spacer structure (e.g., including a first gate spacer 148, 150 and a second gate spacer 170, 172) on a sidewall surface of a gate structure has a fourth dimension 196 (e.g., a lateral dimension or width) in a lateral direction normal to the sidewall surface of the gate structure. The fourth dimension 196 may be a cumulative thickness of the first gate spacer 148, 150 and the second gate spacer 170, 172 in the lateral direction. A thickness of the first gate spacer 148, 150 may be in a range from 2 nm to 10 nm, and a thickness of the second gate spacer 170, 172 may be in a range from 3 nm to 40 nm. In some examples, the fourth dimension 196 may be in a range from 5 nm to 50 nm. According to some examples, the first dimension 190 is less than or equal to the fourth dimension 196, such as in a range of half to one times the fourth dimension 196.

In some examples, the p-type source/drain regions 168 or n-type source/drain regions 166 each form, in part, a metallurgical (e.g., p-n) junction perpendicular to a plane coplanar with the top major surface of the semiconductor substrate 130 at a fifth dimension 198 (e.g., a lateral distance) from the a nearest sidewall surface of a gate structure. Like above, for the pFETs 112, 114, a p-type source/drain region 168 is the p-type region of the metallurgical junction, and the n-type doped well 134 is the n-type region of the metallurgical junction. For the nFETs 122, 124, an n-type source/drain region 166 is the n-type region of the metallurgical junction, and the p-type doped semiconductor material of the semiconductor substrate 130 is the p-type region of the metallurgical junction. The p-type source/drain regions 168 or n-type source/drain regions 166 do not extend under the respective gate structure (e.g., the gate dielectric layer 140, 142 and the gate electrode layer 144, 146). In some examples, the fifth dimension 198 is in a range from 100 Å to 200 Å. As described subsequently, an intermediate gate spacer may be implemented to control the fifth dimension 198 independent of the fourth dimension 196. The source/drain regions may encroach under a respective gate spacer structure based on a dimension of the intermediate gate spacer. Accordingly, examples may achieve the fifth dimension 198 such that a target channel length of a given technology node may be implemented. This may permit a target channel leakage of the technology node to be achieved.

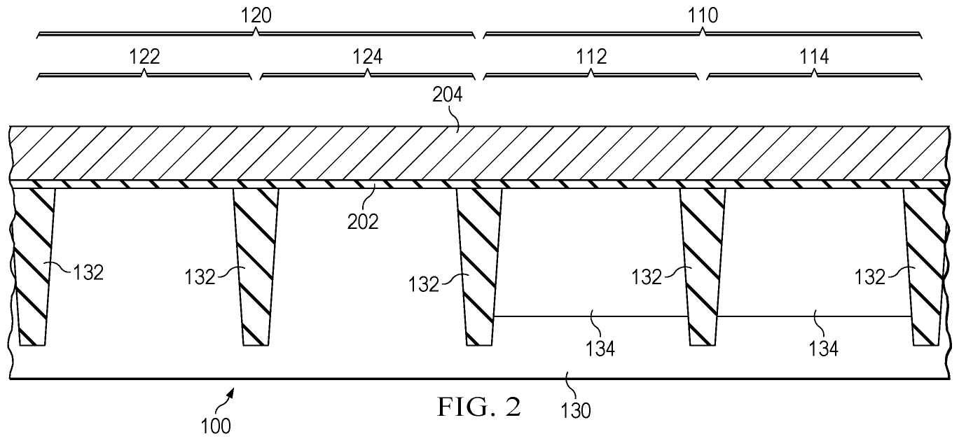

FIGS. 2 through 12 illustrate cross-sectional views of the IC structure 100 of FIG. 1 at various stages of manufacturing according to some examples. Referring to FIG. 2, isolation structures 132 are formed in the semiconductor substrate 130. In the illustrated example, respective trenches are formed in the semiconductor substrate 130, such as by using appropriate photolithography and etching processes. A dielectric liner, such as silicon nitride, is conformally deposited, such as by atomic layer deposition (ALD), chemical vapor deposition (CVD), or the like, in the trenches. An isolation material, such as silicon oxide, is deposited on the dielectric liner in the trenches, such as by flowable CVD (FCVD) or the like. A planarization process, such as a chemical mechanical polish (CMP), may remove any dielectric liner and isolation material on the top major surface of the semiconductor substrate 130. In other examples, a LOCOS process may be used to form the isolation structures 132.

The n-type doped well 134 is formed in the semiconductor substrate 130 in the pFET region 110. The n-type doped well 134 may be formed by masking the nFET region 120 and implanting an n-type dopant into the semiconductor substrate 130 in the pFET region 110. The masking of the nFET region 120 may be by using a photoresist patterned to remain over the nFET region 120. The photoresist may be removed, such as by ashing, after the implantation.

A blanket gate dielectric layer 202 is formed over and on the top major surface of the semiconductor substrate 130. The blanket gate dielectric layer 202 may be any material described above for the gate dielectric layers 140, 142. The blanket gate dielectric layer 202 may be formed by oxidation or deposited by CVD, ALD, or the like.

A blanket gate electrode layer 204 is formed over and on the blanket gate dielectric layer 202. In some examples, the blanket gate electrode layer 204 is a silicon layer (e.g., polysilicon). In such examples, the silicon blanket gate electrode layer 204 is doped with a p-type dopant with a substantially uniform concentration. In some such examples, the silicon blanket gate electrode layer 204 is p-doped in situ during deposition, and in other such examples, the silicon blanket gate electrode layer 204 is blanket implanted with a p-type dopant after deposition. A concentration of the p-type dopant in the silicon blanket gate electrode layer 204 may be in a range from 1×10¹⁹ cm⁻³ to 1×10²¹ cm⁻³ after deposition and/or implantation. In other examples, a different material may be used.

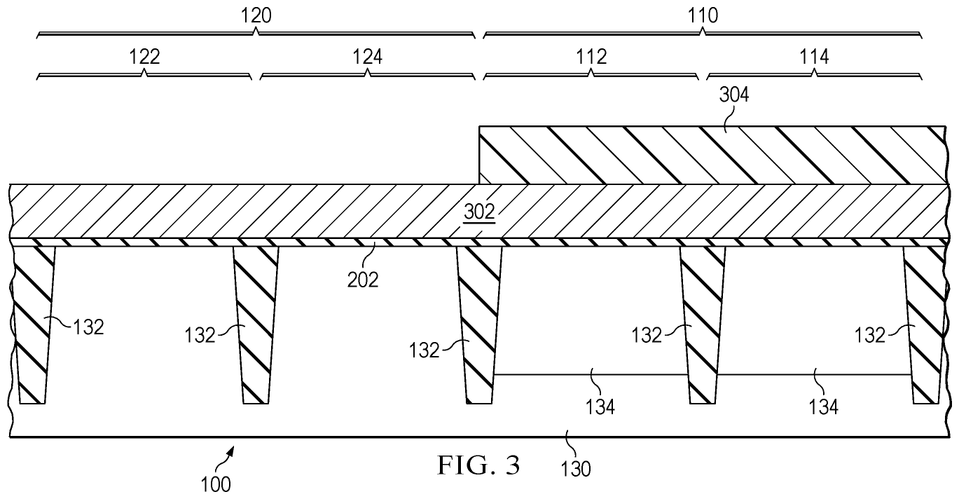

Referring to FIG. 3, the blanket gate electrode layer 204 in the nFET region 120 is implanted with an n-type dopant to form a differential doped blanket gate electrode layer 302. A photoresist 304 is formed over the pFET region 110. The photoresist 304 is deposited (e.g., by spin-on) on or over the blanket gate electrode layer 204 and patterned using photolithography. The photoresist 304 is patterned to remain in the pFET region 110. With the patterned photoresist 304 used as a mask, an implantation is performed to implant the n-type dopant into the blanket gate electrode layer 204 to form the differential doped blanket gate electrode layer 302. After the implantation, the photoresist 304 is removed, such as by ashing. A concentration of the n-type dopant in the differential doped blanket gate electrode layer 302 in the nFET region 120 is greater than a concentration of the p-type dopant in the differential doped blanket gate electrode layer 302 in the pFET region 110. A concentration of the n-type dopant in the differential doped blanket gate electrode layer 302 in the nFET region 120 may be in a range from 5×10¹⁹ cm⁻³ to 5×10²¹ cm⁻³ after the implantation. Continuing the example in which the blanket gate electrode layer 204 is silicon and is p-doped, the implantation may implant n-type dopants to a concentration in the differential doped blanket gate electrode layer 302 that is greater than the concentration of p-type dopants with which the silicon blanket gate electrode layer 204 was doped. Hence, in such examples, the silicon differential doped blanket gate electrode layer 302 is p-doped in the pFET region 110 and is n-doped in the nFET region 120.

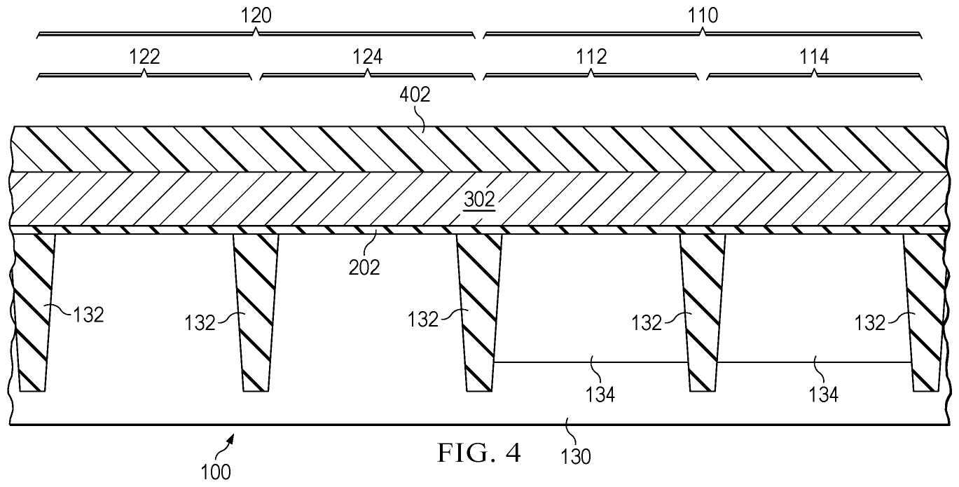

Referring to FIG. 4, a blanket hardmask layer 402 is formed on the differential doped blanket gate electrode layer 302. The blanket hardmask layer 402 may be or include silicon nitride, silicon oxynitride, the like, or a combination thereof. The blanket hardmask layer 402 may be deposited by CVD, physical vapor deposition (PVD), or the like. The blanket hardmask layer 402 may be formed with a thickness in a range from 200 Å to 600 Å.

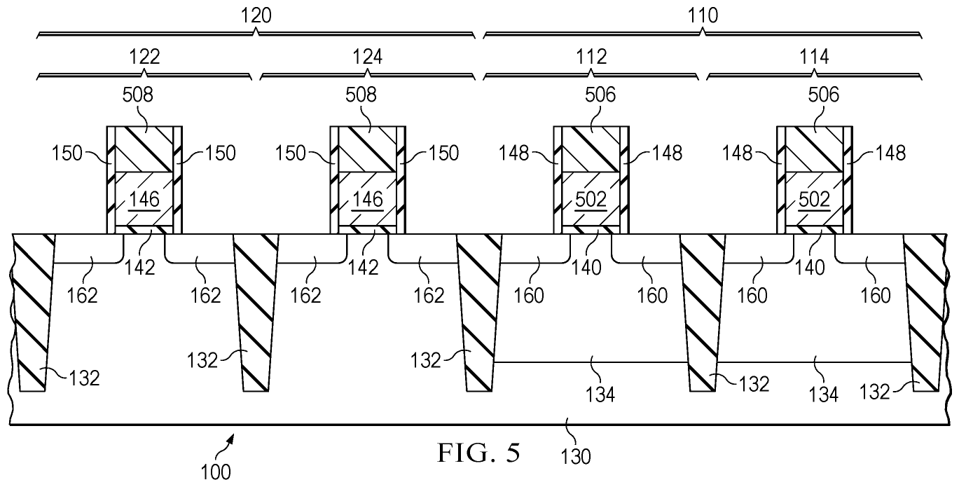

Referring to FIG. 5, the blanket hardmask layer 402, the differential doped blanket gate electrode layer 302, and the blanket gate dielectric layer 202 are patterned into hardmask layers 506, 508, intermediate gate electrode layers 502, 504, and gate dielectric layers 140, 142. The patterning may be by using photolithography and etch processes. The intermediate gate electrode layers 502 subsequently are formed into the gate electrode layers 144, and the intermediate gate electrode layers 504 subsequently are formed into the gate electrode layers 146. Continuing the example in which the blanket gate electrode layer 204 is silicon, per the doping of FIGS. 2 and 3, the intermediate gate electrode layers 502 are p-doped, and the intermediate gate electrode layers 504 are n-doped.

The first gate spacers 148, 150 are formed along sidewall surfaces of the intermediate gate electrode layers 502, 504 and hardmask layers 506, 508. The first gate spacers 148, 150 may be formed by oxidizing the sidewall surfaces or by depositing a layer of the material of the first gate spacers 148, 150 conformally over the semiconductor substrate 130 and anisotropically etching the layer such that the first gate spacers 148, 150 remain.

P-type LDDs 160 and n-type LDDs 162 are formed in the semiconductor substrate 130. The p-type LDDs 160 may be formed by masking the nFET region 120 and implanting a p-type dopant into the semiconductor substrate 130 in the pFET region 110. The masking of the nFET region 120 may be by using a photoresist patterned to remain over the nFET region 120. The photoresist may be removed, such as by ashing, after the implantation. The n-type LDDs 162 may be formed by masking the pFET region 110 and implanting an n-type dopant into the semiconductor substrate 130 in the nFET region 120. The masking of the pFET region 110 may be by using a photoresist patterned to remain over the pFET region 110. The photoresist may be removed, such as by ashing, after the implantation.

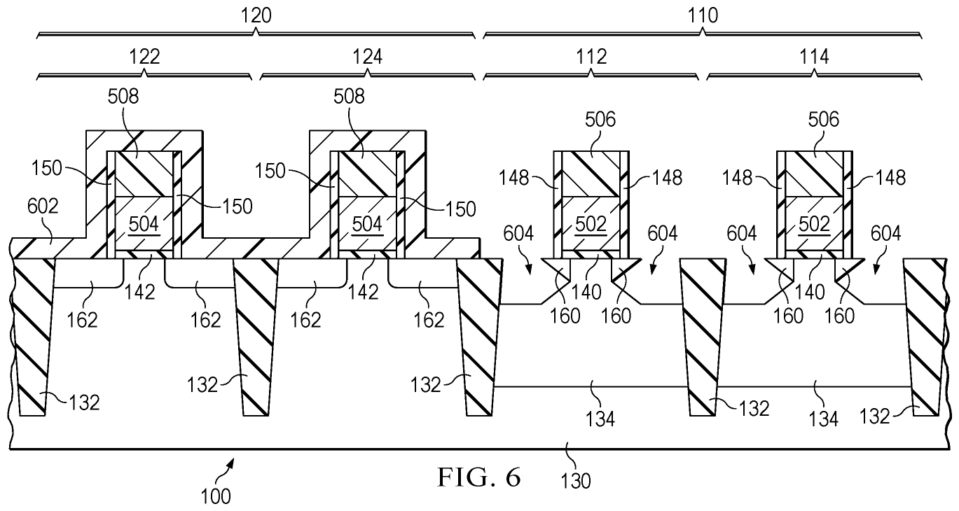

Referring to FIG. 6, a conformal hardmask layer 602 is formed over the semiconductor substrate 130 in the nFET region 120. The conformal hardmask layer 602 is conformally over and on the top major surface of the semiconductor substrate 130 in the nFET region 120, along sidewall and top surfaces of the first gate spacers 150, and over and on top surfaces of the hardmask layers 508. The conformal hardmask layer 602 may be or include silicon nitride, silicon oxynitride, the like, or a combination thereof. The conformal hardmask layer 602 may be formed by conformally depositing and patterning the conformal hardmask layer 602. The conformal hardmask layer 602 may be deposited by CVD, plasma enhanced CVD (PECVD), ALD, or the like. The conformal hardmask layer 602 may be patterned using photolithography and etching processes.

Stressor recesses 604 are formed in the semiconductor substrate 130 in the pFET region 110. The stressor recesses 604 are etched in the semiconductor substrate 130 where the embedded stressors are to be formed. The stressor recesses 604 may be formed using any appropriate etch process, which may be a wet or dry etch process. As illustrated, the etch process may be anisotropic and selective to (e.g., etching preferentially) a crystalline plane of the semiconductor substrate 130.

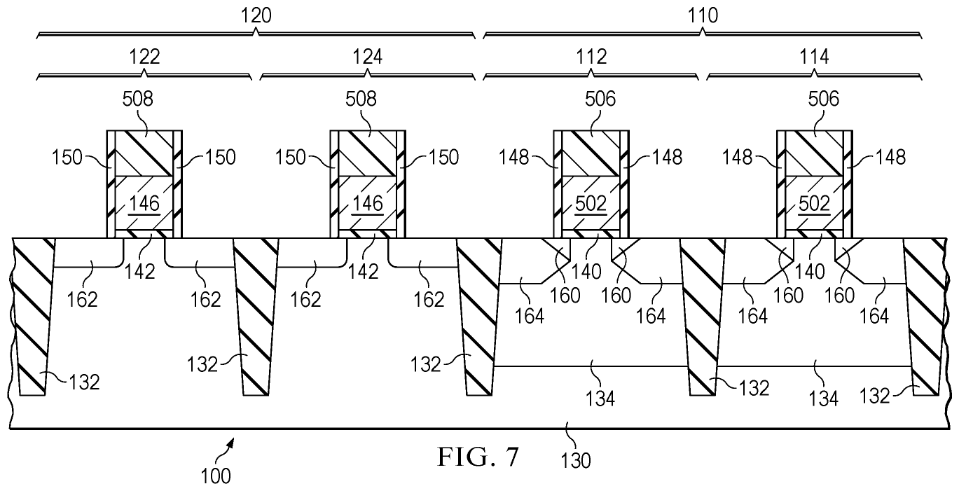

Referring to FIG. 7, embedded stressors 164 are formed in the stressor recesses 604. The embedded stressors 164 may be formed using a selective epitaxial growth process. The embedded stressors 164 may be formed using metal-organic chemical vapor deposition (MOCVD), molecular beam epitaxy (MBE), low pressure chemical vapor deposition (LPCVD) or another epitaxy process. After forming the embedded stressors 164, the conformal hardmask layer 602 is removed. The conformal hardmask layer 602 may be removed by an etch process, which may be a wet or dry etch process.

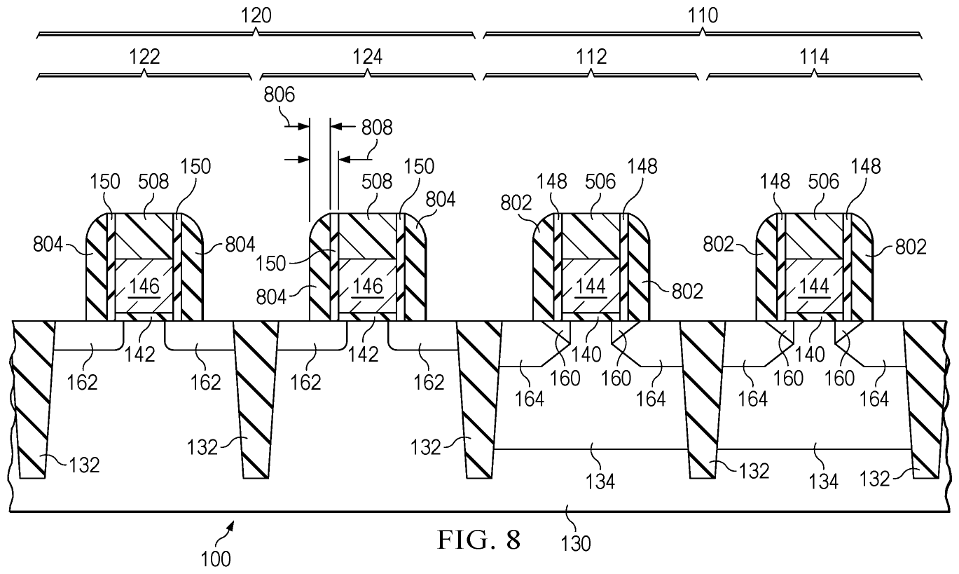

Referring to FIG. 8, intermediate second gate spacers 802, 804 are formed along sidewall surfaces of the first gate spacers 148, 150. The intermediate second gate spacers 802. 804 have a sixth dimension 806 in a lateral direction normal to the sidewall surface of the gate structure (e.g., the intermediate gate electrode layer 502, 504). Further, combined, the first gate spacer 148 and intermediate second gate spacer 802 have a seventh dimension 808 (e.g., a lateral dimension or width) in a lateral direction normal to the sidewall surface of the gate structure (e.g., the intermediate gate electrode layer 502, 504). The intermediate second gate spacers 802, 804 may be or include silicon nitride, silicon oxynitride, the like, or a combination thereof. The intermediate second gate spacers 802, 804 may be formed by conformally depositing and anisotropically etching a layer of the material of the intermediate second gate spacers 802, 804. The layer of the intermediate second gate spacers 802, 804 may be deposited by CVD, PECVD. ALD, or the like. In some examples, the material of the intermediate second gate spacers 802. 804 is the same as the material of the hardmask layers 506, 508. The layer of the intermediate second gate spacers 802, 804 may be deposited with a thickness that is the sixth dimension 806. The anisotropic etch may be a reactive ion etch (RIE) or the like. The combined dimension (e.g., a total thickness) of the intermediate gate electrode layer 502, 504 and the hardmask layer 506, 508 permits the sixth dimension 806 to be sufficiently large for a target alignment of source/drain regions as described in more detail subsequently.

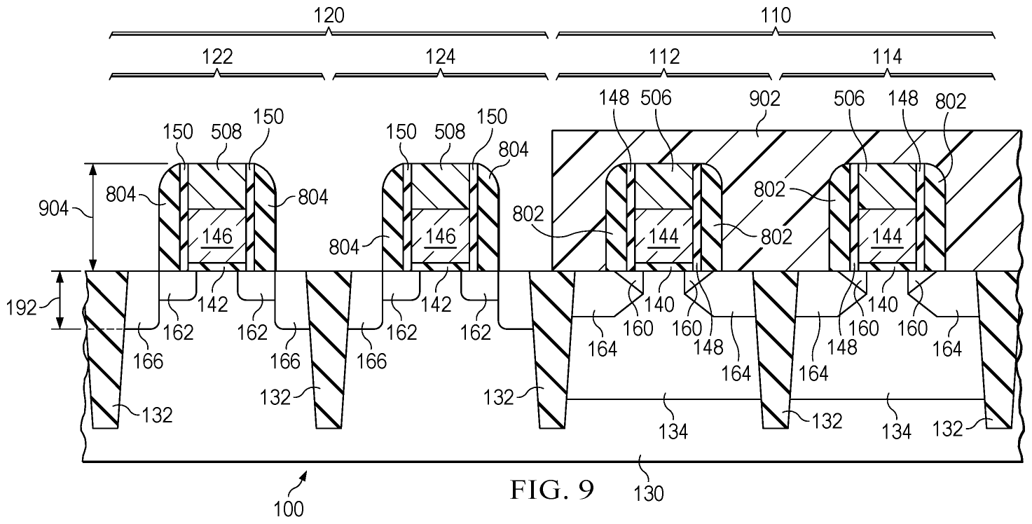

Referring to FIG. 9, an implantation in the nFET region 120 is performed to form the n-type source/drain regions 166 in the semiconductor material of the semiconductor substrate 130 laterally proximate the intermediate gate electrode layers 504 (which correspond to the gate electrode layers 146). A photoresist 902 is formed over the pFET region 110. The photoresist 902 is deposited (e.g., by spin-on) on or over the semiconductor substrate 130 and patterned using photolithography. The photoresist 902 is patterned to remain in the pFET region 110. With the patterned photoresist 902 used as a mask, an implantation is performed to implant the n-type dopant into the semiconductor substrate 130 to form the n-type source/drain regions 166. The n-type source/drain regions 166 have the concentration of the n-type dopant as described above after the implantation. After the implantation, the photoresist 902 is removed, such as by ashing.

The hardmask layers 508 are over and on the intermediate gate electrode layers 504 during the implantation of FIG. 9. The implantation of FIG. 9 (to form the n-type source/drain regions 166) may also implant the n-type dopant into the intermediate gate electrode layers 504 and the hardmask layers 508. Implanting the n-type dopant into the intermediate gate electrode layers 504 results in the gate electrode layers 146, which are doped with an n-type dopant concentration as described above with respect to FIG. 1. During the implantation of FIG. 9, the stacks, each including the gate dielectric layer 142, the intermediate gate electrode layer 504, and the hardmask layer 508, have an eighth dimension 904 from the top major surface of the semiconductor substrate 130 to a top surface of the respective stack (e.g., a top surface of the hardmask layer 508). The eighth dimension 904 is equal to or greater than the second dimension 192. Hence, the stacks (e.g., including the hardmask layers 508) have sufficient eighth dimensions 904 (e.g., thicknesses) to block or prevent dopants of the implantation of FIG. 9 from reaching the semiconductor substrate 130 in the channel region underlying the respective stack. The channel regions underlying the gate electrode layers 146 and gate dielectric layers 142 may therefore be substantially free from the dopant used to form the n-type source/drain regions 166. If, for example, a shorter stack, such as of only the intermediate gate electrode layer 504 and gate dielectric layer 142 (e.g., without a hardmask layer), is implemented during the implantation of FIG. 9, channel regions may be implanted with the dopant rendering the nFETs 122, 124 inoperable, and/or the metallurgical junctions may not be sufficiently deep (e.g., if the implant energy is reduced to avoid implanting the channel region) causing the nFETs 122, 124 to have undesirable characteristics, such as higher resistance, lower on-state current, among others.

Additionally, the implantation of FIG. 9 is performed while the intermediate second gate spacers 804 have the sixth dimension 806. The implantation may be performed perpendicularly to the top major surface of the semiconductor substrate 130 or at a small angle, such as within 5°, with respect to perpendicular to the top major surface of the semiconductor substrate 130. Hence, the metallurgical (e.g., p-n) junctions of the n-type source/drain regions 166 perpendicular to a plane coplanar with the top major surface of the semiconductor substrate 130 generally align with or correspond to an outer sidewall surface of a respective intermediate second gate spacer 804 to control the fifth dimension 198 described with reference to FIG. 1. Because of the eighth dimension 904 of the stack, the intermediate second gate spacer 804 may be formed with the sixth dimension 806, which may be present during the implantation of FIG. 9. The sixth dimension 806 may permit the n-type source/drain regions 166 to be formed such that the n-type source/drain regions 166 do not extend under the gate structures (e.g., sufficiently away from the gate structures), which may permit a target channel length and channel leakage of a given technology node to be achieved. If, for example, a shorter stack, such as of only the intermediate gate electrode layer 504 and gate dielectric layer 142 (e.g., without a hardmask layer), is implemented during the implantation of FIG. 9, the stack may not support a spacer with a sufficient thickness to obtain the target channel length, which may result in undesirable channel leakage, among other things.

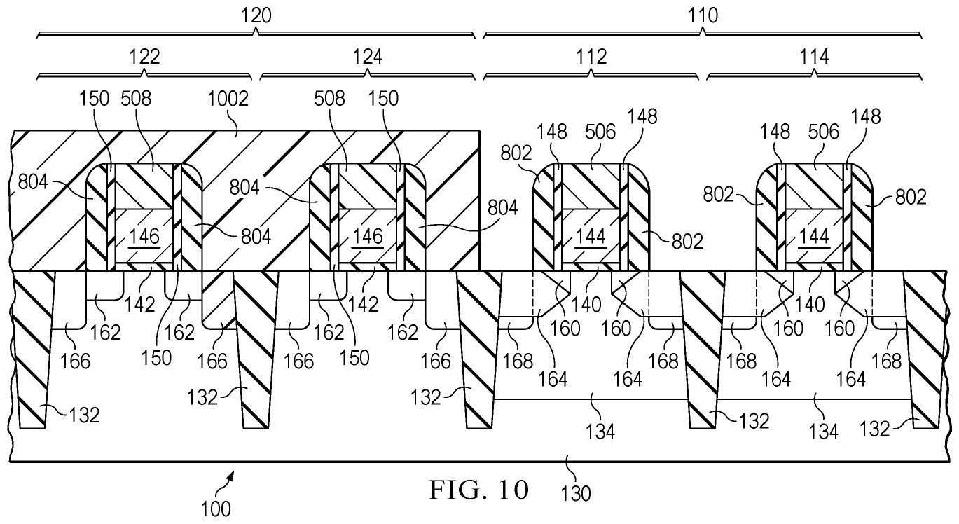

Referring to FIG. 10, an implantation in the pFET region 110 is performed to form the p-type source/drain regions 168 in the embedded stressors 164 and in the semiconductor material of the semiconductor substrate 130 laterally proximate the intermediate gate electrode layers 502 (which correspond to the gate electrode layers 144). A photoresist 1002 is formed over the nFET region 120. The photoresist 1002 is deposited (e.g., by spin-on) on or over the semiconductor substrate 130 and patterned using photolithography. The photoresist 1002 is patterned to remain in the nFET region 120. With the patterned photoresist 1002 used as a mask, an implantation is performed to implant the p-type dopant into the semiconductor substrate 130 to form the p-type source/drain regions 168. The p-type source/drain regions 168 have the concentration of the p-type dopant as described above after the implantation. After the implantation, the photoresist 1002 is removed, such as by ashing.

The hardmask layers 506 are over and on the intermediate gate electrode layers 502 during the implantation of FIG. 10. The implantation of FIG. 10 (to form the p-type source/drain regions 168) may also implant the p-type dopant into the intermediate gate electrode layers 502 and the hardmask layers 506. Implanting the p-type dopant into the intermediate gate electrode layers 502 results in the gate electrode layers 144, which are doped with a p-type dopant concentration as described above with respect to FIG. 1. During the implantation of FIG. 10, the stacks, each including the gate dielectric layer 140, the intermediate gate electrode layer 502, and the hardmask layer 506, have the eighth dimension 904 from the top major surface of the semiconductor substrate 130 to a top surface of the respective stack (e.g., a top surface of the hardmask layer 506), as described above. Hence, the stacks (e.g., including the hardmask layers 506) have sufficient eighth dimensions 904 (e.g., thicknesses) to block or prevent dopants of the implantation of FIG. 10 from reaching the semiconductor substrate 130 in the channel region underlying the respective stack. The channel regions underlying the gate electrode layers 144 and gate dielectric layers 140 may therefore be substantially free from the dopant used to form the p-type source/drain regions 168. If, for example, a shorter stack, such as of only the intermediate gate electrode layer 502 and gate dielectric layer 140 (e.g., without a hardmask layer), is implemented during the implantation of FIG. 10, channel regions may be implanted with the dopant rendering the pFETs 112, 114 inoperable, and/or the metallurgical junctions may not be sufficiently deep (e.g., if the implant energy is reduced to avoid implanting the channel region) causing the pFETs 112, 114 to have undesirable characteristics, such as higher resistance, lower on-state current, among others.

Additionally, the implantation of FIG. 10 is performed while the intermediate second gate spacers 802 have the sixth dimension 806 (e.g., a lateral dimension or width). The implantation may be performed perpendicularly to the top major surface of the semiconductor substrate 130 or at a small angle, such as within 5°, with respect to perpendicular to the top major surface of the semiconductor substrate 130. Hence, the metallurgical (e.g., p-n) junctions of the p-type source/drain regions 168 perpendicular to a plane coplanar with the top major surface of the semiconductor substrate 130 generally align with or correspond to an outer sidewall surface of a respective intermediate second gate spacer 802 to control the fifth dimension 198 described with reference to FIG. 1. Because of the eighth dimension 904 of the stack, the intermediate second gate spacer 802 may be formed with the sixth dimension 806, which may be present during the implantation of FIG. 10. The sixth dimension 806 may permit the p-type source/drain regions 168 to be formed such that the p-type source/drain regions 168 do not extend under the gate structures (e.g., sufficiently away from the gate structures), which may permit a target channel length and channel leakage of a given technology node to be achieved. If, for example, a shorter stack, such as of only the intermediate gate electrode layer 502 and gate dielectric layer 140 (e.g., without a hardmask layer), is implemented during the implantation of FIG. 10, the stack may not support a spacer with a sufficient thickness to obtain the target channel length, which may result in undesirable channel leakage, among other things.

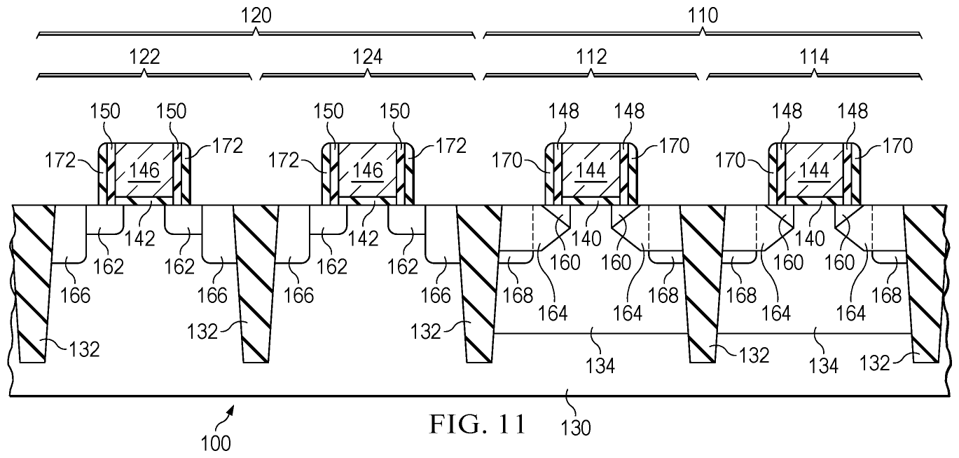

Referring to FIG. 11, the hardmask layers 506, 508 are removed. The hardmask layers 506, 508 may be removed using an etch selective to (e.g., preferentially etching) the hardmask layers 506, 508, which may be a wet etch.

In some examples, the intermediate second gate spacers 802, 804 are thinned (e.g., a lateral thickness is reduced) to result in the second gate spacers 170, 172. The thinning may be by a timed isotropic etch selective to (e.g., preferentially etching) the material of the intermediate second gate spacers 802, 804. The thinning of the intermediate second gate spacers 802, 804 to obtain the second gate spacers 170, 172 results in the fourth dimension 196 described with reference to FIG. 1 being less than the seventh dimension 808. The thinning of the intermediate gate spacers 802, 804 may result in thinner gate spacer structures that may be decoupled from, to some extent, the sixth dimension 806, which may be implemented to permit the source/drain regions to be formed without extending under the respective gate structures.

In some examples, the intermediate second gate spacers 802, 804 are removed, and the second gate spacers 170, 172 are subsequently formed. In some examples, the intermediate second gate spacers 802, 804 are removed simultaneously (e.g., by a same etch) with the hardmask layers 506, 508. The intermediate second gate spacers 802, 804 may be removed by an etch selective to (e.g., etching preferentially) the material of the intermediate second gate spacers 802, 804 (and the materials of the hardmask layers 506, 508). The second gate spacers 170, 172 may be formed by conformally depositing and anisotropically etching a layer of the material of the second gate spacers 170, 172. The layer of the second gate spacers 170, 172 may be deposited by CVD, PECVD, ALD, or the like. The layer of the second gate spacers 170, 172 may be deposited with a thickness that is less than the sixth dimension 806. The anisotropic etch may be a RIE or the like. The thinner second gate spacers 170, 172 (e.g., relative to the intermediate second gate spacers 802, 804) results in the fourth dimension 196 being less than the seventh dimension 808. The removal of the intermediate gate spacers 802, 804 and subsequent formation of the second gate spacers 170, 172 may result in thinner gate spacer structures that may be decoupled from, to some extent, the sixth dimension 806, which may be implemented to permit the source/drain regions to be formed without extending under the respective gate structures.

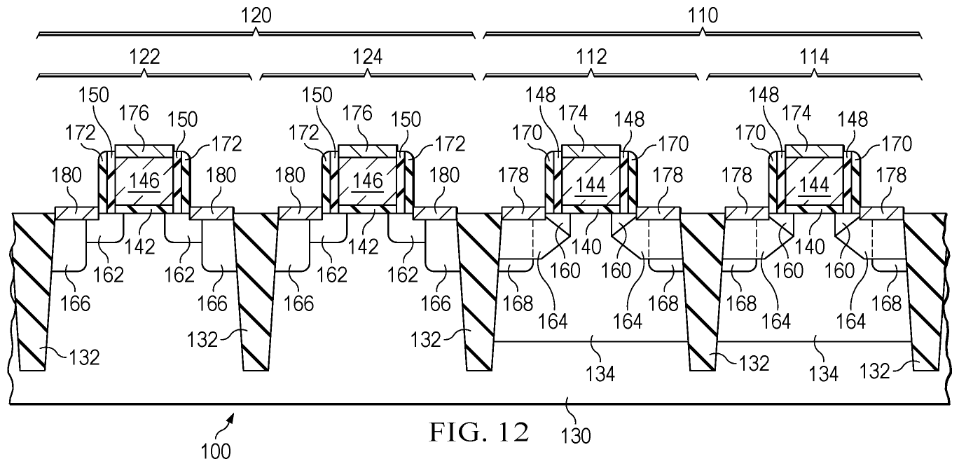

Referring to FIG. 12, metal-semiconductor compound 174, 176, 178, 180 are formed. The metal-semiconductor compound 174, 176, 178, 180 may be formed by depositing a metal (e.g., Ti, Co, Ni, Pt) over the semiconductor substrate 130, such as by CVD, PVD, or the like. The metal is reacted with a semiconductor material, such as the semiconductor material of the semiconductor substrate 130 (e.g., silicon) and a semiconductor material (e.g., silicon, such as polysilicon) of the gate electrode layers 144, 146. An anneal process may be used to cause the metal to react with a semiconductor material. Any unreacted metal may be removed, such as by an etch selective to (e.g., etching preferentially) the metal.

Referring to FIG. 1, a conformal dielectric layer 182 is formed over the semiconductor substrate 130. The conformal dielectric layer 182 may be conformally deposited using CVD, PECVD, ALD, or the like. Subsequently, a dielectric layer 184 is formed over the conformal dielectric layer 182. The dielectric layer 184 may be deposited using any appropriate deposition process, such as PECVD or the like. The dielectric layer 184 may be planarized, such as by a CMP.

The contacts 186 are formed through the dielectric layer 184 and the conformal dielectric layer 182 to the respective metal-semiconductor compound 174, 176, 178, 180. Respective openings may be formed through the dielectric layer 184 and the conformal dielectric layer 182 to the metal-semiconductor compound 174, 176, 178, 180 using appropriate photolithography and etching processes. A metal(s) of the contacts 186 are deposited in the openings through the dielectric layer 184 and the conformal dielectric layer 182. The metal(s) may be deposited using an appropriate deposition process(es), such as CVD, PVD, or the like. Any excess metal(s) may be removed, such as by a CMP and/or by patterning using photolithography and etch processes.

Although various examples have been described in detail, it should be understood that various changes, substitutions, and alterations can be made therein without departing from the scope defined by the appended claims.

What is claimed is:

1. A semiconductor device, comprising:
a substrate comprising a semiconductor material;
a gate dielectric layer on a surface of the substrate;
a gate electrode layer on the gate dielectric layer;
a doped source/drain region in the substrate, wherein:
the doped source/drain region has a metallurgical junction in the substrate, the metallurgical junction being parallel to a plane coplanar with the surface of the substrate;
the metallurgical junction extends to a first vertical distance from the surface of the substrate;
the gate electrode layer has a top surface distal from the substrate;
the top surface of the gate electrode layer is a second vertical distance away from the surface of the substrate; and
the second vertical distance is equal to or less than half of the first vertical distance; and
a dielectric layer over the substrate and the gate electrode layer.

2. The semiconductor device of claim 1, further comprising a silicide, wherein the gate electrode layer comprises a polysilicon layer on the gate dielectric layer, the silicide being on the polysilicon layer.

3. The semiconductor device of claim 1, wherein the second vertical distance is less than 600 Angstroms (Å).

4. The semiconductor device of claim 1, wherein a portion of the semiconductor material under the gate dielectric layer is substantially free of a dopant of the doped source/drain region.

5. The semiconductor device of claim 1, wherein the gate dielectric layer has a dielectric constant greater than silicon dioxide (SiO₂).

6. The semiconductor device of claim 1, wherein the gate electrode layer has a lateral dimension parallel to a channel length direction from the doped source/drain region, the second vertical distance being less than or equal to twice the lateral dimension.

7. The semiconductor device of claim 1 further comprising a gate spacer structure along a sidewall surface of the gate electrode layer, wherein:
the gate spacer structure has a lateral width in a direction normal to the sidewall surface of the gate electrode layer; and
the second vertical distance is less than or equal to the lateral width.

8. The semiconductor device of claim 1, wherein the doped source/drain region is in the semiconductor material of the substrate, the metallurgical junction being in the semiconductor material of the substrate.

9. The semiconductor device of claim 1, wherein:
the substrate includes a stressor material; and
the doped source/drain region is in the stressor material and the semiconductor material of the substrate, the metallurgical junction being in the semiconductor material of the substrate.

10. A method, comprising:
forming a gate stack on a gate dielectric layer disposed on a surface of a semiconductor substrate, the gate stack including a gate electrode layer and a hardmask layer over the gate electrode layer;
while the hardmask layer is over the gate electrode layer, forming a source/drain region in the semiconductor substrate, forming the source/drain region comprising implanting a dopant into the semiconductor substrate; and
after implanting the dopant, forming a dielectric layer over the gate electrode layer.

11. The method of claim 10, further comprising:
forming a gate spacer along a sidewall surface of the gate stack before forming the source/drain region; and
reducing a lateral thickness of the gate spacer after forming the source/drain region.

12. The method of claim 10, further comprising:
forming a first gate spacer along a sidewall surface of the gate stack before forming the source/drain region;
removing the first gate spacer after forming the source/drain region; and
forming a second gate spacer along the sidewall surface of the gate stack.

13. The method of claim 10, wherein:
the semiconductor substrate includes a semiconductor material, at least a portion of the semiconductor material being underneath the gate dielectric layer and the gate stack; and
implanting the dopant into the semiconductor substrate includes implanting the dopant into the semiconductor material of the semiconductor substrate laterally proximate to the gate stack.

14. The method of claim 10, further comprising forming a stressor material in the semiconductor substrate laterally proximate to the gate stack, wherein:
the semiconductor substrate includes a semiconductor material, at least a portion of the semiconductor material underneath the gate dielectric layer and the gate stack; and
implanting the dopant into the semiconductor substrate includes implanting the dopant into the stressor material and the semiconductor material of the semiconductor substrate laterally proximate to the gate stack.

15. The method of claim 10, further comprising, before forming the dielectric layer, removing the hardmask layer.

16. The method of claim 15, wherein removing the hardmask layer includes removing a gate spacer along a sidewall surface of the gate stack.

17. The method of claim 10, wherein after forming the dielectric layer:
the source/drain region has a metallurgical junction in the semiconductor substrate, wherein the metallurgical junction is parallel to a plane coplanar with the surface of the semiconductor substrate;
the metallurgical junction extends to a first vertical distance from the surface of the semiconductor substrate;
the gate electrode layer has a top surface distal from the semiconductor substrate;
the top surface of the gate electrode layer is a second vertical distance away from the surface of the semiconductor substrate; and
the second vertical distance being equal to or less than half of the first vertical distance.

18. A semiconductor device, comprising:
a transistor including:
a first source/drain region in a semiconductor substrate;
a second source/drain region in the semiconductor substrate; and
a gate electrode layer over the semiconductor substrate and laterally between the first source/drain region and the second source/drain region, wherein:
a top surface of a semiconductor material of the semiconductor substrate underlies the gate electrode layer;
the first source/drain region has a metallurgical junction in the semiconductor substrate, the metallurgical junction being parallel to a plane coplanar with the top surface;
the metallurgical junction extends to a first vertical distance from the top surface;
the gate electrode layer has a top surface distal from the semiconductor substrate;
the top surface of the gate electrode layer is a second vertical distance away from the top surface; and
the second vertical distance is equal to or less than half of the first vertical distance; and
a dielectric layer over the transistor.

19. The semiconductor device of claim 18, wherein the second vertical distance is less than 600 Angstroms (Å).

20. The semiconductor device of claim 18, wherein the gate electrode layer has a lateral distance parallel to a direction from the first source/drain region to the second source/drain region, the second vertical distance being less than or equal to twice the lateral distance.

21. The semiconductor device of claim 18 further comprising a gate spacer along a sidewall surface of the gate electrode layer, wherein:
the gate spacer has a lateral width in a direction normal to the sidewall surface of the gate electrode layer; and
the second vertical distance is less than or equal to the lateral width.

22. The semiconductor device of claim 18, further comprising a silicide, wherein the gate electrode layer comprises a polysilicon layer over the semiconductor substrate, the silicide being on the polysilicon layer.
